(19) United States
(12) Patent Application Publication
(10) Pub. No.: US 2015/0295114 A1
(43) Pub. Date: Oct. 15, 2015

(54) MULTI-JUNCTION POWER CONVERTER WITH PHOTON RECYCLING

(71) Applicant: Sempruis, Inc., Durham, NC (US)

(72) Inventors: Matthew Meitl, Durham, NC (US); Brent Fisher, Durham, NC (US); John Wilson, Overland Park, KS (US); Scott Burroughs, Raleigh, NC (US); Steven Seel, Cary, NC (US)

(21) Appl. No.: 14/683,498

(22) Filed: Apr. 10, 2015

Related U.S. Application Data
(60) Provisional application No. 61/978,569, filed on Apr. 11, 2014.

(51) Int. Cl. H01L 31/0687; H01L 31/0304; H01L 31/028; H01L 31/0693; H01L 31/043

(52) U.S. Cl. CPC H01L 31/0687; H01L 31/0693; H01L 31/043; H01L 31/028; H01L 31/0304; H01L 31/03046

(57) ABSTRACT

A multi-junction power converter system illuminated by an incident light source includes a multi-layer stack having a plurality of junctions defined by materials having different bandgaps, with an upper junction having a higher bandgap, and junctions therebelow having smaller bandgaps. The upper junction absorbs more of the incident light, whereas lower junctions successively absorb less of the remaining incident light. The junctions below the upper junction are supplied with additional illumination that has been reemitted from previous cells due to photon recycling. Related devices and methods of operation are also discussed.

### CLAIM OF PRIORITY

This application claims priority under 35 USC §119(e) from U.S. Provisional Patent Application No. 61/978,569 entitled “MULTI-JUNCTION LASER POWER CONVERTER WITH PHOTON RECYCLING” filed on Apr. 11, 2014, the disclosure of which is incorporated by reference herein in its entirety.

### FIELD

The invention relates to power conversion devices, and more particularly, to laser power converters and/or LED-driven power converters.

### BACKGROUND

Solar cells, including multi-junction solar cells that have substantially similar bandgaps (in which a top cell receives incident light and a second cell subsequently receives any transmitted light), may be used in laser power conversion. Power converters can also include laser power conversion devices in which sub-cell thickness optimization may be used to achieve current matching conditions.

Two-junction or multi-junction laser power converters, where the first cell is about 500 nm-600 nm thick and the second is between about 600 nm and 3000 nm thick and made from GaAs, InGsAsP, InGaP, InGaAlP, InGaAs, GaSb, or AlGaAs, have also been used. Some converters may also include laser power converters with only two junctions in which the band gaps are not similar, as well as laser power converters that deliver illumination via an optical fiber plus atmosphere.

### SUMMARY

According to some embodiments of the present invention, a multi-junction photovoltaic cell includes a multi-layer stack including a plurality of photovoltaic cells electrically connected in series. The photovoltaic cells are formed of respective materials, at least some of which have different bandgaps, which are vertically stacked in order of decreasing bandgap relative to a surface of the multi-layer stack that is configured to receive incident illumination, such as narrowband illumination from a laser light source. Ones of the photovoltaic cells further from the incident illumination receive additional illumination that has been reemitted from ones of the photovoltaic cells closer to the incident illumination due to a photon recycling effect. As such, despite mismatching of the bandgaps of the photovoltaic cells with respect to the wavelength of incident illumination (for instance, when the incident illumination is provided by a single wavelength or other narrowband light source) or otherwise unequal absorption of the incident illumination among the cells, the respective photovoltaic cells may nevertheless provide substantially equal current output.

According to some embodiments, a multi-junction power converter system includes a multi-junction photovoltaic cell having n junctions defining a stack of n cells, where n is an integer greater than 1. The n junctions have different bandgaps from one another. One of the n junctions, which is positioned in the stack to be closer to an incident light source, has a higher bandgap than ones of the n junctions positioned therebelow, which have progressively smaller bandgaps with distance from the incident light source. The one of the n junctions that is positioned to be closer to the incident light source is configured to absorb more than 1/n of incident light, and a next one of the n junctions positioned therebelow in the stack is configured to absorb more than 1/(n−1) of remaining incident light, such that the ones of the n junctions are configured to progressively absorb reduced incident light with distance from the incident light source. The ones of the n junctions are configured to be supplied with additional illumination that has been reemitted from one of the n junctions thereabove to produce photon recycling.

In some embodiments, said photon recycling in said multi-junction power converter may be configured to distribute current generation substantially equally among the n cells.

In some embodiments, said incident light source may be a laser.

In some embodiments, the incident light source may be a broad band light source including an LED or an LED in combination with a phosphor.

In some embodiments, ones of the n junctions may be InGaP, GaAs, and InGaAsN, respectively.

In some embodiments, ones of the n junctions may be InGaP, GaAs, and Ge, respectively.

According to further embodiments, a multi-junction power converter includes a multi-junction photovoltaic cell having n junctions that define a stack of cells, where the n junctions have similar bandgaps. Outer ones of the n junctions in the stack are configured to absorb less than 1/n of incident light, and inner ones of the n junctions in the stack are configured to absorb more than 1/n of the incident light. The outer ones of the n junctions are configured to be supplied with additional illumination that has been reemitted from the inner ones of the n junctions to produce photon recycling, such that current generation responsive to said incident light and said photon recycling is substantially equal among the cells of the stack.

In some embodiments, said incident light may be provided by a laser light source.

In some embodiments, said incident light may be provided by an LED light source or an LED plus phosphor light source.

In some embodiments, said photon recycling may be designed to provide a higher efficiency than provided by cells having respective thicknesses that are optimized or designed for a single illumination wavelength.

According to still other embodiments, a multi-junction photovoltaic cell includes a multi-layer stack having a plurality of photovoltaic cells that are electrically connected. The photovoltaic cells respectively include materials having different bandgaps, and are vertically stacked in order of decreasing bandgap relative to a surface of the multi-layer stack that is configured to receive incident illumination. One of the photovoltaic cells closer to the incident illumination is configured to emit photons responsive to the incident light, and one of the photovoltaic cells further from the incident illumination is configured to absorb the photons emitted from the one of the photovoltaic cells closer to the incident illumination, such that the photovoltaic cells are configured to generate respective output currents that are substantially equal.

In some embodiments, the photovoltaic cells may be configured to generate respective currents that are unequal in response to the incident illumination. The respective currents may be portions of the respective output currents.

In some embodiments, at least one of the photovoltaic cells may have a bandgap that is substantially mismatched with respect to a wavelength of the incident illumination such that absorption of the incident illumination is unequal among the photovoltaic cells. For example, in some embodiments, the incident illumination may be narrowband or substantially single-wavelength light, such as provided by a laser light source, while in other embodiments, the incident light source may be a broad band light source, such as an LED or an LED in combination with a phosphor.

In some embodiments, a thickness of at least one of the photovoltaic cells may be designed such that absorption of the incident illumination is unequal among the photovoltaic cells.

In some embodiments, the photovoltaic cells may be lattice-matched with ones of the photovoltaic cells thereabove and therebelow in the multi-layer stack.

In some embodiments, ones of the photovoltaic cells may include InGaP, GaAs, and GaInNAsSb, respectively.

In some embodiments, ones of the photovoltaic cells may include AlGaAs, InGaAlP, and Ge, respectively.

More generally, embodiments of the present invention may achieve output current matching among photovoltaic cells having the same or different bandgaps by utilizing photon recycling to compensate for varying or substantially unequal current generation from each cell in response to the incident illumination, allowing for greater flexibility with regard to sources and/or wavelengths of input illumination.

Other devices and/or methods of operation according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1 is a block diagram illustrating elements of a laser power conversion system in accordance with some embodiments of the present invention.

FIGS. 2A and 2B are cross-sectional views illustrating multi-junction cells that may be used in power conversion systems in accordance with some embodiments of the present invention.

FIG. 3 illustrates photon recycling in a three junction power converter that may be used in power conversion systems in accordance with some embodiments of the present invention.

FIG. 4 is a cross-sectional view illustrating a multi-junction cell that may be used in power conversion systems in accordance with further embodiments of the present invention.

### DETAILED DESCRIPTION

Embodiments of the present invention provide power converters that may provide higher voltage outputs than possible with traditional single junction power conversion devices. Embodiments of the present invention may further employ semiconductor material stacks that are not specifically designed for laser power conversion. Other related advantages according to embodiments of the present invention may include the ability to amortize production costs for multi-junction materials across a wider range of devices beyond power converters.

Embodiments of the present invention may also achieve less costly and higher voltage output converters that can be more efficiently manufactured, and may allow for the use of less stringent tolerances with respect to the layer thicknesses and/or material bandgaps used in the converters.

Higher voltage output converters according to embodiments of the present invention may also use a wider range of light sources with higher efficiency, in addition to monochromatic laser illumination, so as to accommodate wider band illumination from LEDs and other sources.

Higher output voltage converters according to embodiments of the present invention may further provide the capability of dual high efficiency conversion, by being able to convert both laser illumination and solar illumination in the same converter. In addition, higher voltage output converters according to embodiments of the present invention may also make use of photon recycling to achieve higher current generation.

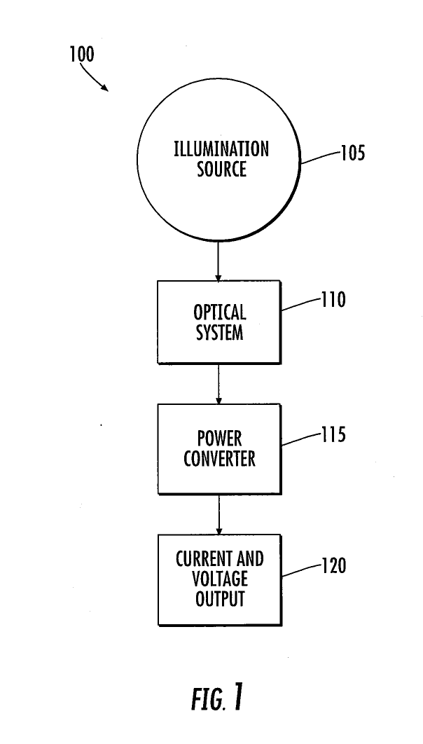

FIG. 1 depicts elements of a laser power conversion system 100 according to some embodiments of the present invention that includes an illumination source 105, an optical system 110 for delivering illumination, and a power converter 115 (such as a laser power converter), which produces voltage and current output 120. In an example embodiment, the power conversion system 100 of FIG. 1 includes a multi-junction photovoltaic cell that exhibits photon recycling, wherein the structure of the cell is designed or otherwise configured to use the photon recycling to deliver improved performance. In such a cell, the layer thickness of the top cell is designed or otherwise configured to absorb (and thus, produce electric current from) at least a fraction of the incident light greater than 1/n, where n is the number of junctions in the cell.

In the power conversion system 100 of FIG. 1, the illumination source 105 may be a monochromatic light source having a wavelength selected for improved or optimal driving of the multi-junction photovoltaic cell. In contrast to some conventional power conversion systems, the light source laser wavelength is chosen relative to the quantum efficiency of the various cell layers (generally referred to herein as “cells” or “sub cells”) of the multi-junction photovoltaic cell, such that current generation in each cell is matched or substantially equal when photon recycling is accounted for or otherwise taken into consideration. An optical system 110 provides for transmission or delivery of the light from the light source 105 to the power converter 115. The power converter 115 provides current and voltage output 120 responsive to the light received from the illumination source 105 via the optical system 110.

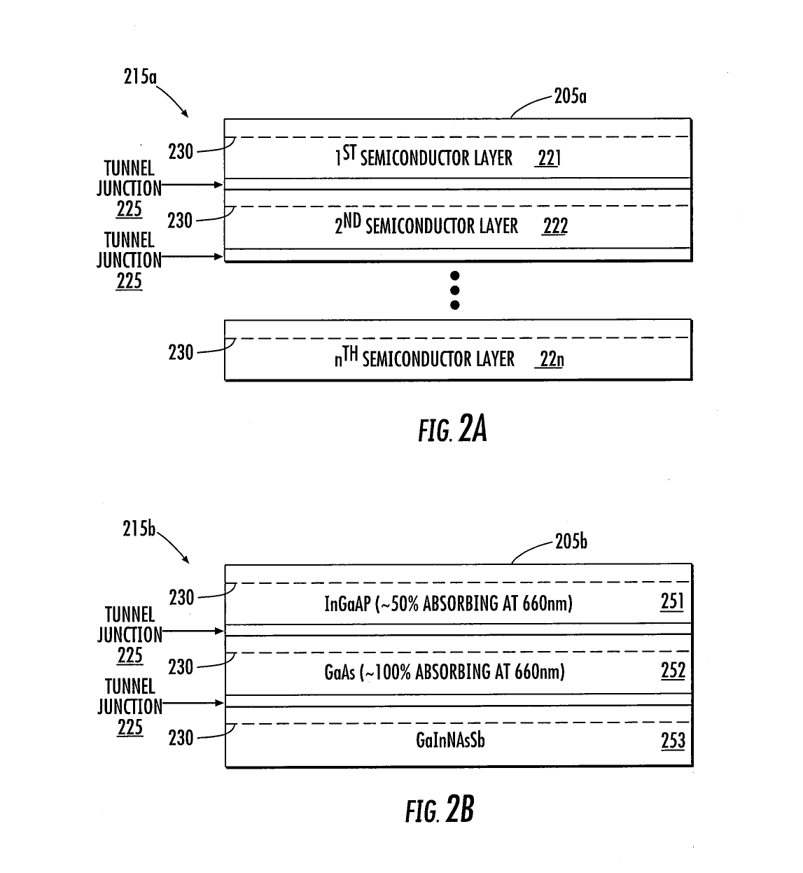

FIG. 2A illustrates an embodiment of the invention where a monochromatic light source is used as the illumination source 105. In the example of FIG. 2A, the power converter 115 includes a multi-junction cell 215a. The multi-junction cell 215a includes a multi-layer stack having n p-n junctions 230 (each junction being or defining a cell 221, 222, . . . 22n, where n is an integer greater than 1) electrically connected in series and separated by low-absorbing tunnel junctions 225 provided between each of the three cells 221, 222, . . . 22n.

The materials of the multi-junction cell 215a of FIG. 2A can be formed by molecular beam epitaxy on a substrate (for example, a gallium arsenide (GaAs) substrate), with lattice matching maintained through some or all layers of material. The multi-junction cell 215a shown in FIG. 2A includes first semiconductor layer 221 defining a top cell, a second semiconductor layer 222 defining a middle cell, and an nth semiconductor layer 22n defining a bottom cell. At least some of the semiconductor layers 222 . . . 22n are vertically stacked in order of decreasing bandgap relative to a surface 205a of the first semiconductor layer 221 of the multi-layer stack, which is positioned or otherwise arranged to receive incident illumination from the light source. For example, the second semiconductor layer 222 may be formed of a semiconductor material having a lower bandgap than that of the first semiconductor layer 221, and the nth semiconductor layer 22n may be formed of a semiconductor material having a lower bandgap than that of the second semiconductor layer 222.

In some embodiments, the multi-junction cell 215a of FIG. 2A can be prepared on a ceramic or silicon substrate using microtransfer printing. For example, arrays of vertically stacked cells can be fabricated using transfer-printing processes similar to those described, for example, in U.S. Pat. No. 7,972,875 to Rogers et al. entitled “Optical Systems Fabricated By Printing-Based Assembly,” the disclosure of which is incorporated by reference herein in its entirety. The individual cells (also referred to herein as ‘subcells’) can be designed or otherwise configured to increase or maximize the capture of light, and may be grown on separate source substrates in some embodiments and assembled using micro-transfer printing as described, for example, in U.S. patent application Ser. No. 14/211,708 to Meitl et al. entitled “High Efficiency Solar Devices Including Stacked Solar Cells For Concentrator Photovoltaics,” the disclosure of which is incorporated by reference herein in its entirety.

FIG. 2B illustrates an embodiment of the invention where a laser monochromatic light source having a wavelength near 660 nm is used as the illumination source 105. In the example of FIG. 2B, the power converter 115 includes a multi-junction cell 215b. The multi-junction photovoltaic cell 215b has three p-n junctions 230 (each junction being or defining a cell 251, 252, 253) electrically connected in series and separated by low-absorbing tunnel junctions 225 provided between each of the three cells 251, 252, 253.

The materials of the multi-junction cell 215b of FIG. 2B can be formed by molecular beam epitaxy on a GaAs substrate, with lattice matching maintained through some or all layers of material. In particular, the multi-junction cell 215b shown in FIG. 2B includes an InGaP top cell 251 (including an incident light-receiving surface 205b) with a bandgap of about 1.9 eV, a GaAs middle cell 252 with a bandgap of about 1.4 eV, and a dilute nitride bottom cell (illustrated as a GaInNAsSb cell 253) with a bandgap of about 1.0 eV. The multi-junction cell 215b of FIG. 2B can be prepared on a ceramic or silicon substrate using microtransfer printing. For example, arrays of vertically stacked cells can be fabricated using transfer-printing processes similar to those described, for example, in U.S. Pat. No. 7,972,875 to Rogers et al. The individual cells can be designed or otherwise configured to increase or maximize the capture of light, and may be grown on separate source substrates in some embodiments and assembled using micro-transfer printing as described, for example, in U.S. patent application Ser. No. 14/211,708 to Meitl et al.

Thus, in some embodiments of the present invention, a multi-junction laser power converter includes a stack of n junctions (where n is an integer greater than 1), and each of the n junctions are defined by materials having different bandgaps from one another. The topmost junction in the stack (which is positioned nearest to the incident illumination) has the highest bandgap, and each junction below in the stack has a progressively smaller bandgap. Thus, the top junction absorbs substantially more than 1/n of the incident light, while the next junction therebelow absorbs substantially more than 1/(n−1) of the remaining incident light, and similarly for the lower junctions.

According to embodiments of the present invention, each cell below the top cell is supplied with additional illumination that has been reemitted from previous cells thereabove in the stack, producing a photon recycling effect. Photon recycling thus distributes or otherwise results in current generation that is substantially similar among the respective cells, in a way that may not be otherwise realized for stacks including junctions having non-equal bandgaps.

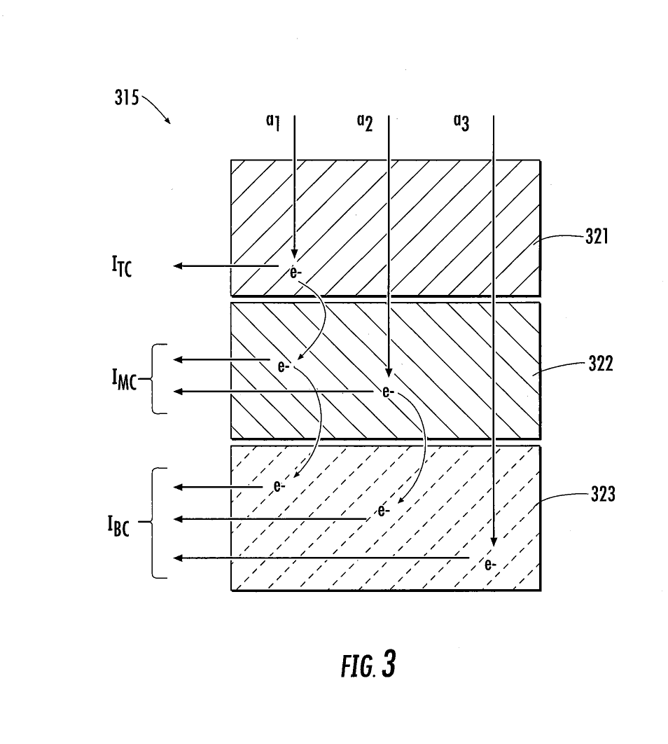

FIG. 3 illustrates photon recycling in a three junction power converter 315. In this illustration, the total current generated by each cell is indicated by Iₓ with horizontal arrows (where x=TC(top cell) 321, MC(middle cell) 322, BC(bottom cell) 323), while the path of incident light photons before being absorbed is indicated by a_{y} with the vertical arrows (where y=1, 2, 3). The symbols e⁻ indicate that photons have been absorbed to create electron-hole pairs in a given material, and the curved arrows indicate that the electron-hole pair has recombined and emitted a photon which is absorbed by a layer below it.

The above process of electron-hole pair recombination and emission of a photon that is reabsorbed by another layer is the process of photon recycling, which may contribute to several advantages provided by embodiments of the invention. The multiplicity of horizontal arrows in the bottom cell 323 compared to the top cell 321 indicates the greater number of pathways by which current can be generated in the lower cells despite the initial absorption of a laser wavelength in the earlier higher bandgap cells. The effect is to increase the current generated by lower-bandgap cells 322, 323 that would not otherwise absorb as high a fraction of the incident light as the top cell 321, by allowing incident photons another chance to be collected by being absorbed in lower-bandgap cells 322, 323. This is a process by which photon recycling enables embodiments of the invention to use materials of non-equal bandgaps that may not be perfectly matched to the illumination wavelength, such that the absorption of the incident light a_{y} into each layer 321, 322, 323 is not equal for all layers 321, 322, 323. As such, multi-junction power converters in accordance with embodiments of the present invention may be used with light sources having a wide range of illumination wavelengths, allowing for greater flexibility in the design and use of such devices in a variety of environments.

In some embodiments of the invention, the monochromatic light source is a laser, such as a laser with a wavelength near 660 nm. The multi-junction photovoltaic cell has three junctions electrically connected in series and separated by low-absorbing tunnel junctions. Those tunnel junctions are located in between the three cells. In some embodiments, the materials for multi-junction cells are formed by molecular beam epitaxy (MBE) or Metalorganic Chemical Vapor Deposition (MOCVD) or Organometallic Vapor Phase Epitaxy (OMVPE) on a GaAs substrate with lattice matching maintained through all layers of material. In the example of FIG. 3, the multi-junction cell 315 includes an InGaP top cell 321 with a bandgap of about 1.9 eV, a GaAs middle cell 322 with a bandgap of about 1.4 eV, and a dilute nitride bottom cell with a bandgap of about 1.0 eV. The multi-junction cell 315 may be prepared on a ceramic or silicon substrate using microtransfer printing as described, for example, in U.S. patent application Ser. No. 14/211,708 to Meitl et al.

In some embodiments of the invention, the multi-junction cell may be prepared by dicing the substrate wafer upon which the cell was grown, instead of using microtransfer printing.

In some embodiments the bottom junction may be a germanium cell with a bandgap of 0.7 eV. In further embodiments the bottom cell may be SiGe. In still further embodiments, the bottom cell may be InGaAs. In yet further embodiments, the top and middle cells may be AlGaAs and InGaAlP, respectively. In some embodiments, the light source may be an LED.

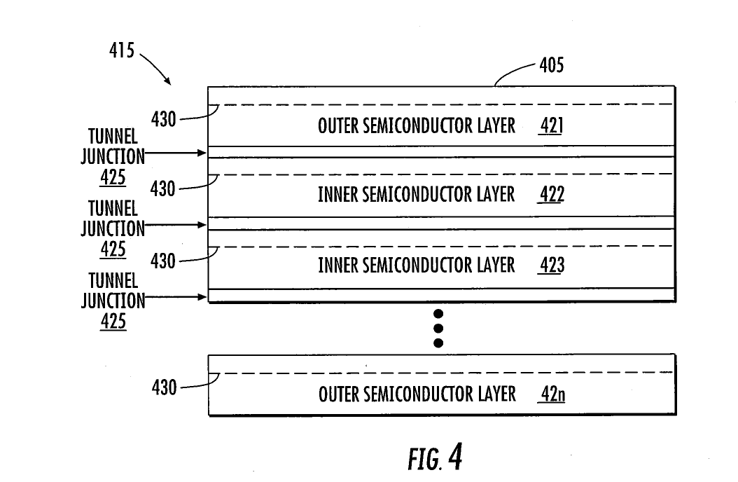

FIG. 4 is a cross-sectional view illustrating a multi-junction cell 415 that may be used in power conversion systems in accordance with further embodiments of the present invention. In the example of FIG. 4, a multi-junction cell 415 includes a multi-layer stack having n p-n junctions 430 (each junction being or defining a cell 421, 422, 423 . . . 42n, where n is an integer greater than 1) electrically connected in series and separated by low-absorbing tunnel junctions 425 provided between each of the three cells 421, 422, 423 . . . 42n, where each of the n junctions 430 are defined by semiconductor materials or compounds having the same or similar bandgaps.

The materials of the multi-junction cell 415 of FIG. 4 can be formed by molecular beam epitaxy on a substrate (for example, a gallium arsenide (GaAs) substrate), with lattice matching maintained through some or all layers of material. The multi-junction cell 415 shown in FIG. 4 includes outer semiconductor layers 421 and 42n in the stack 415 defining top and bottom (or exterior) cells, respectively, and inner semiconductor layers 422 and 423 defining interior cells. The outer semiconductor layers 421 and 42n (and their respective junctions 430) are configured to absorb less than 1/n of the incident light on light receiving surface 405, while the inner semiconductor layers 422 and 423 (and their respective junctions 430) are configured to absorb more than 1/n of the incident light. However, the outer semiconductor layers 421 and 42n receive photons that are reemitted from the inner ones of the n junctions in response to the incident light, to produce photon recycling. As such, in the multi-junction cell 415 of FIG. 4, the current generation is substantially equal among the cells 421, 422, 423 . . . 42n.

Thus, in further embodiments, a multi-junction laser power converter includes n junctions (where n is an integer greater than 1), and each of the n junctions are defined by semiconductor materials or compounds having the same or similar bandgaps. Despite unequal absorption of incident light among the cells (for example, where the cell bandgaps are not perfectly matched to the illumination wavelength), the outer cells are supplied with additional illumination that has been reemitted from inner cells in the stack, producing a photon recycling effect. Photon recycling thus distributes or otherwise results in current generation that is substantially similar among the respective cells. As such, multi-junction power converters in accordance with embodiments of the present invention may be used with light sources having a wide range of illumination wavelengths, allowing for greater flexibility in the design and use of such devices in a variety of environments.

Although described above primarily with respect to 3-junction cells with reference to particular materials, it will be understood that embodiments of the present invention are not so limited. As such, in multi-junction photovoltaic cells in accordance with embodiments of the present invention, there may be fewer or more than 3 junctions, using any combinations of the materials mentioned above, or other materials. Also, in some embodiments the cells may be silicon, copper indium gallium selenide (GIGS), or cadmium telluride (CdTe). In other words, the above embodiments are examples of the multiple possible embodiments of the invention and are not intended to be limitations. Other materials and configurations can be used within the scope and spirit of the invention and photon recycling.

The present invention has been described above with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. In no event, however, should “on” or “directly on” be construed as requiring a layer to cover an underlying layer.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entireties.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments of the present invention described herein, and of the manner and process of making and using them, and shall support claims to any such combination or subcombination.

In the specification, there have been disclosed embodiments of the invention and, although specific terms are employed, they are used in a generic and descriptive sense only and not for purposes of limitation, the scope of the present invention being set forth in the following claims.

1. A multi-junction power converter, said multi-junction power converter comprising:
a multi-junction photovoltaic cell including n junctions defining a stack of n cells, wherein n is an integer greater than 1,
wherein the n junctions have different bandgaps from one another;
wherein one of the n junctions that is positioned in the stack to be closer to an incident light source has a higher bandgap than ones of the n junctions positioned therebelow, which have progressively smaller bandgaps with distance from the incident light source;
wherein the one of the n junctions that is positioned to be closer to the incident light source is configured to absorb more than 1/n of incident light, and wherein a next one of the n junctions positioned therebelow in the stack is configured to absorb more than 1/(n−1) of remaining incident light, such that the ones of the n junctions are configured to progressively absorb reduced incident light with distance from the incident light source; and
wherein the ones of the n junctions are configured to be supplied with additional illumination that has been reemitted from one of the n junctions thereabove to produce photon recycling.

2. The multi-junction power converter of claim 1, wherein said photon recycling in said multi-junction power converter is configured to distribute current generation substantially equally among the n cells.

3. The multi-junction power converter of claim 1, wherein said incident light source is a laser.

4. The multi-junction power converter of claim 1, wherein the incident light source is a broad band light source comprising an LED or an LED in combination with a phosphor.

5. The multi-junction power converter of claim 1, wherein the n junctions comprise InGaP, GaAs, and InGaAsN, respectively.

6. The multi-junction power converter of claim 1, wherein the n junctions comprise InGaP, GaAs, and Ge, respectively.

7. A multi-junction power converter, comprising:
a multi-junction photovoltaic cell that includes n junctions that define a stack of cells,
wherein the n junctions have similar bandgaps;
wherein outer ones of the n junctions in the stack are configured to absorb less than 1/n of incident light;
wherein inner ones of the n junctions in the stack are configured to absorb more than 1/n of the incident light;
wherein the outer ones of the n junctions are configured to be supplied with additional illumination that has been reemitted from the inner ones of the n junctions to produce photon recycling; and
wherein current generation responsive to said incident light and said photon recycling is substantially equal among the cells of the stack.

8. The multi-junction power converter of claim 7, wherein said incident light is provided by a laser light source.

9. The multi-junction power converter of claim 7, wherein said incident light is provided by an LED light source or an LED plus phosphor light source.

10. The multi-junction power converter of claim 7, wherein said photon recycling is configured to provide a higher efficiency than that provided by cells having respective thicknesses optimized for a single illumination wavelength.

11. A multi-junction photovoltaic cell, comprising:
a multi-layer stack comprising a plurality of photovoltaic cells that are electrically connected, wherein the photovoltaic cells respectively comprise materials having different bandgaps and are vertically stacked in order of decreasing bandgap relative to a surface of the multi-layer stack that is configured to receive incident illumination,
wherein one of the photovoltaic cells closer to the incident illumination is configured to emit photons responsive to the incident light, and wherein one of the photovoltaic cells further from the incident illumination is configured to absorb the photons emitted from the one of the photovoltaic cells closer to the incident illumination,
and wherein the photovoltaic cells are configured to generate respective output currents that are substantially equal.

12. The multi-junction photovoltaic cell of claim 11, wherein the photovoltaic cells are configured to generate respective currents that are unequal in response to the incident illumination, and wherein the respective currents comprise portions of the respective output currents.

13. The multi-junction photovoltaic cell of claim 12, wherein at least one of the photovoltaic cells comprises a bandgap that is substantially mismatched with respect to a wavelength of the incident illumination such that absorption of the incident illumination is unequal among the photovoltaic cells.

14. The multi-junction photovoltaic cell of claim 13, wherein the incident illumination comprises narrowband or single-wavelength light.

15. The multi-junction photovoltaic cell of claim 13, wherein the incident illumination comprises broadband light.

16. The multi-junction photovoltaic cell of claim 12, wherein at least one of the photovoltaic cells comprises a thickness such that absorption of the incident illumination is unequal among the photovoltaic cells.

17. The multi-junction photovoltaic cell of claim 12, wherein the photovoltaic cells are lattice-matched with ones of the photovoltaic cells thereabove and therebelow in the multi-layer stack.

18. The multi-junction photovoltaic cell of claim 11, wherein the photovoltaic cells comprise InGaP, GaAs, and GaInNAsSb, respectively.

19. The multi-junction photovoltaic cell of claim 11, wherein the photovoltaic cells comprise AlGaAs, InGaAlP, and Ge, respectively.
